(19) United States
(12) Patent Application Publication
(10) Pub. No.: US 2023/0411185 A1
(43) Pub. Date: Dec. 21, 2023

(54) BRIDGE APPARATUS AND METHOD FOR SEMICONDUCTOR DIE TRANSFER

(71) Applicant: Rohinni, LLC, Coeur d'Alene, ID (US)

(72) Inventors: Nicholas Steven Busch, Spokane, WA (US); Justin Wendt, Post Falls, ID (US)

(21) Appl. No.: 17/824,887

(22) Filed: May 25, 2022

(51) Int. Cl. H01L 21/67; H01L 21/683

(52) U.S. Cl. CPC H01L 21/67132; H01L 21/6836; H01L 21/67144

(57) ABSTRACT

An apparatus for transferring a semiconductor die (“die”) from the first substrate to the second substrate. The apparatus includes a stage configured to hold a product substrate. A bridge holds a transfer mechanism assembly and a die substrate holder configured to hold the first substrate. A controller is configured to cause the bridge and the transfer mechanism assembly and the die substrate holder to move to align the transfer mechanism assembly with the die on the first substrate with a transfer position on the second substrate where the die is to be transferred.

### CROSS REFERENCE TO RELATED PATENT APPLICATIONS

This application incorporates: U.S. patent application Ser. No. 14/939,896, filed on Nov. 12, 2014, entitled “Apparatus for Transfer of Semiconductor Devices,” now patented as U.S. Pat. No. 9.633,883; U.S. patent application Ser. No. 15/343,055, filed on Nov. 3, 2016, entitled “Compliant Needle for Direct Transfer of Semiconductor Devices;” U.S. patent application Ser. No. 15/360,471, filed on Nov. 23, 2016, entitled “Top-Side Laser for Direct Transfer of Semiconductor Devices;” U.S. patent application Ser. No. 15/360,645, filed on Nov. 23, 2016, entitled “Pattern Array Direct Transfer Apparatus and Method Therefor;” U.S. patent application Ser. No. 15/409,409, filed on Jan. 18, 2017, entitled “Flexible Support Substrate for Transfer of Semiconductor Devices;” U.S. patent application Ser. No. 15/987,094, filed on May 12, 2018, entitled “Method and Apparatus for Multiple Direct Transfers of Semiconductor Devices;” and U.S. patent application Ser. No. 16/147,456, filed on Sep. 28, 2018, entitled “Method and Apparatus for Increased Transfer Speed of Semiconductor Devices,” now patented as U.S. Pat. No. 11,094,571; all of which are incorporated in their entireties by reference.

### BACKGROUND

Semiconductor devices are electrical components that utilize semiconductor material, such as silicon, germanium, gallium arsenide, and the like. Semiconductor devices are typically manufactured as single discrete devices or as integrated circuits (ICs). Examples of single discrete devices include electrically-actuatable elements such as light-emitting diodes (LEDs), diodes, transistors, resistors, capacitors, fuses, and the like.

The fabrication of semiconductor devices typically involves an intricate manufacturing process with a myriad of steps. The end-product of the fabrication is a “packaged” semiconductor device. The “packaged” modifier refers to the enclosure and protective features built into the final product as well as the interface that enables the device in the package to be incorporated into an ultimate circuit.

The conventional fabrication process for semiconductor devices starts with handling a semiconductor wafer. The wafer is diced into a multitude of “unpackaged” semiconductor devices. The “unpackaged” modifier refers to an unenclosed semiconductor device without protective features. Herein, one or more unpackaged semiconductor devices may be called semiconductor device die, or just “die” for simplicity. A single semiconductor wafer may be diced to create die of various sizes, so as to form upwards of more than 100,000 or even 1,000,000 die from the semiconductor wafer (depending on the starting size of the semiconductor), and each die has a certain quality. The unpackaged die are then “packaged” via a conventional fabrication process discussed briefly below. The actions between the wafer handling and the packaging may be referred to as “die preparation.”

In some instances, the die preparation may include sorting the die via a “pick and place process,” whereby diced die are picked up individually and sorted into bins. The sorting may be based on the forward voltage capacity of the die, the average power of the die, and/or the wavelength of the die.

Typically, the packaging involves mounting a die into a plastic or ceramic package (e.g., mold or enclosure). The packaging also includes connecting the die contacts to pins/wires for interfacing/interconnecting with ultimate circuitry. The packaging of the semiconductor device is typically completed by sealing the die to protect it from the environment (e.g., dust).

A product manufacturer then places packaged semiconductor devices in product circuitry. Due to the packaging, the devices are ready to be “plugged in” to the circuit assembly of the product being manufactured. Additionally, while the packaging of the devices protects them from elements that might degrade or destroy the devices, the packaged devices are inherently larger (e.g., in some cases, around 10 times the thickness and 10 times the area, resulting in 100 times the volume) than the die found inside the package. Thus, the resulting circuit assembly cannot be any thinner than the packaging of the semiconductor devices.

### BRIEF DESCRIPTION OF THE DRAWINGS

The Detailed Description is set forth with reference to the accompanying figures. In the figures, the left-most digit(s) of a reference number identifies the figure in which the reference number first appears. The use of the same reference numbers in different figures indicates similar or identical items. Furthermore, the drawings may be considered as providing an approximate depiction of the relative sizes of the individual components within individual figures. However, the drawings are not to scale, and the relative sizes of the individual components, both within individual figures and between the different figures, may vary from what is depicted. In particular, some of the figures may depict components as a certain size or shape, while other figures may depict the same components on a larger scale or differently shaped for the sake of clarity.

FIG. 1 illustrates a schematic view of an embodiment of elements of a die transfer system, according to this disclosure.

FIG. 2 illustrates a schematic view of an example transfer apparatus with a bridge apparatus for transfer of die from a die substrate to a product substrate according to this disclosure.

FIG. 3 illustrates a schematic view of an example transfer apparatus with multiple transfer mechanisms and die substrates on a single bridge apparatus for transfer of die from the die substrates to a product substrate according this disclosure.

FIG. 4 illustrates a schematic view of an example transfer apparatus with a first transfer mechanism assembly and first die substrate on a first bridge and a second transfer mechanism assembly and second die substrate on a second bridge for transfer of die from the die substrates to a product substrate according to this disclosure.

FIG. 5 illustrates a plan view of an embodiment of a product substrate having a circuit trace thereon according to this disclosure.

FIG. 6 illustrates a method of a die transfer operation according to this disclosure.

FIG. 7 illustrates a method of a die transfer operation according to this disclosure.

FIG. 8 illustrates a method of a die transfer process from a die substrate and transfer mechanism held by a shared bridge, according to this disclosure.

### DETAILED DESCRIPTION

This disclosure is directed to a machine that directly transfers and affixes semiconductor device die to a circuit, a process for achieving the same, and a circuit having die affixed thereto (e.g., the completed circuit being the output product. Notably, it is considered that even a product made using an embodiment of the disclosed machine and process is an improved produce compared to one made otherwise, since the improvements to a product created via an embodiment of the disclosed machine and/or method may impart additional improvements to the output product.) In an embodiment, the machine functions to transfer unpackaged die directly from a substrate such as a “wafer tape” to a product substrate, such as a circuit substrate. The direct transfer of unpackaged die may significantly reduce the thickness of an end product compared to a similar product produced by conventional means, as well as the amount of time and/or cost to manufacture the product substrate.

For the purpose of this description, the term “substrate” refers to any substance on which, or to which, a process or action occurs. Further, the term “product” refers to the desired output from a process or action, regardless of the state of completion, which is subjective to the user/receiver. Thus, a product substrate refers to any substance on which, or to which, a process or action is caused to occur for a desired output. Herein, the term “product substrate” may include, but is not limited to: a wafer tape (for example, to presort the die and create sorted die sheets for future use); a paper or polymer substrate formed as a sheet or other non-planar shape, where the polymer—translucent or otherwise—may be selected from any suitable polymers, including, but not limited to, a silicone, an acrylic, a polyester, a polycarbonate, etc.; a circuit board (such as a printed circuit board (PCB)); a string or thread circuit, which may include a pair of conductive wires or “threads” extending in parallel; and a cloth material of cotton, nylon, rayon, leather, etc. The choice of material of the product substrate may include durable materials, flexible materials, rigid materials, and other materials with which the transfer process is successful and which maintain suitability for the end use of the product substrate. The product substrate may be formed solely or at least partially of conductive material such that the product substrate acts as a conductive circuit for forming a product. The potential types of product substrate may further include items, such as glass bottles, vehicle windows, or sheets of glass.

In an embodiment, the product substrate may include a circuit trace disposed thereon. The circuit trace, as depicted, may include a pair of adjacent trace lines spaced apart by a trace spacing, or gap so as to accommodate a distance between electrical contact terminals (not shown) on the die being transferred. Thus, the trace spacing, or gap between the adjacent trace lines of the circuit trace may be sized according to the size of the die being transferred to ensure proper connectivity and subsequent activation of the die. For example, the circuit trace may have a trace spacing, or gap ranging from about 10 to 200 microns, about 100 to 175 microns, or about 125 to 150 microns.

The circuit trace may be formed from a conductive ink disposed via screen printing, inkjet printing, laser printing, manual printing, or other printing means. Further, the circuit trace may be pre-cured and semi-dry or dry to provide additional stability, while still being activatable for die conductivity purposes. A wet conductive ink may also be used to form the circuit trace, or a combination of wet and dry ink may be used for the circuit trace. Alternatively, or additionally, the circuit trace may be pre-formed as a wire trace, or photo-etched, or from molten material formed into a circuit pattern and subsequently adhered, embedded, or otherwise secured to the product substrate.

The material of the circuit trace may include, but is not limited to, silver, copper, gold, carbon, conductive polymers, etc. In an embodiment, the circuit trace may include a silver-coated copper particle. A thickness of the circuit trace may vary depending on the type of material used, the intended function and appropriate strength or flexibility to achieve that function, the energy capacity, the size of the LED, etc. For example, a thickness of the circuit trace may range from about 5 microns to 20 microns, from about 7 microns to 15 microns, or from about 10 microns to 12 microns.

Accordingly, in one non-limiting example, the product substrate may be a flexible, translucent polyester sheet having a desired circuit pattern screen printed thereon using a silver-based conductive ink material to form the circuit trace.

In an embodiment, the machine may secure a product substrate for receiving “unpackaged” die, such as LEDs, transferred from the wafer tape, for example. In an effort to reduce the dimensions of the products using the die, the die may be very small and thin. For example, a die may be about 50 microns thick, or more or less. In other cases, the die may be under 30 microns thick, or more or less. The thickness may be measured as the total height of the die. In an embodiment, the die thickness may range from 3 microns to 100 microns, or from 15 microns to 85 microns, or from 35 microns to 65 microns, or from 45 microns to 55 microns, for example. In general, anything less than 100 microns is considered in the industry to be a “microLED.” Nevertheless, in an embodiment, the die (e.g., LED, etc.) may be a miniLED, having a thickness ranging from about 100 microns to about 200 microns. It should, however, be noted that the systems and methods, as disclosed herein, may be applied to die thicknesses greater than 50 microns, such as 200 microns thickness or greater. Regardless, due to the relatively small size of the die, the machine includes components that function to precisely align both the wafer tape carrying the die and transfer mechanism with the transfer location on the product substrate to ensure accurate placement and/or avoid product material waste. In an embodiment, the components that align the transfer mechanism and the die on the wafer tape may include a bridge to which the wafer tape and the transfer mechanism are secured separately and independently and conveyed individually to a position of alignment such that a specific die on the wafer tape is transferred to a specific spot on the product substrate.

In an embodiment, the machine further includes a transfer mechanism for transferring the die directly from the wafer tape to the product substrate without “packaging” the die. The transfer mechanism may be disposed vertically above the wafer tape so as to press down on the die via the wafer tape toward the product substrate. This process of pressing down on the die may cause the die to peel off of the wafer tape, starting at the sides of the die until the die separate from the wafer tape to be attached to the product substrate. That is, by reducing the adhesion force between the die and the wafer tape and increasing the adhesion force between the die and the product substrate, the die may be transferred.

In an embodiment, the transfer mechanism may include an elongated rod, such as a pin or needle that may be cyclically actuated against the wafer tape to push the wafer tape from a top side. Note, for the sake of convenience and clarity, hereinafter, the term “needle” is used predominantly to refer to the portion of the transfer mechanism that is a form of an elongated rod, as disclosed herein. Nevertheless, it is contemplated that those skilled in the art will understand that other forms of elongated rods may be known or referenced by other terms that would be satisfactory substitutes for the instant use of “needle.” The end of the needle may be sized so as to be no wider than a width of the die being transferred. Although not shown, in a different embodiment, it is contemplated that the width of the end needle may be wider than a width of the die. When the end of the needle contacts the wafer tape, the wafer tape may experience a local deflection at the area between the die and the wafer tape. Inasmuch as the deflection is highly localized and rapidly performed, the portion of the wafer tape that does not receive pressure from the needle may begin to flex away from the surface of the die. This partial separation may thus cause the die to lose sufficient contact with the wafer tape, so as to be released from the wafer tape. Moreover, in an embodiment, the deflection of the wafer tape may be so minimal, as to maintain an entirety of the surface area of the die in contact with the wafer tape, while still causing the opposing surface of the die to extend beyond a plane of extension of the corresponding surface of the adjacent die to avoid unintentional transfer of the adjacent die.

In an embodiment, the transfer apparatus may include one or more bridge structures that hold a frame carrying the die substrate and the transfer mechanism assembly. Similar to other embodiments described herein, the die substrate may be wafer tape with semiconductor die attached thereto. The transfer mechanism assembly may include a pin actuator that is configured to actuate a pin that, when aligned, presses a die from the die substrate onto the product substrate. In an embodiment, the product substrate may be disposed on a stage that is configured to translate the product substrate in a first direction. The one or more bridge structures may also be configured to move, and therefore, move the die substrate and the transfer mechanism assembly in substantially the same first direction. The die substrate and/or the transfer mechanism may be coupled to the bridge by one or more motors and/or actuation systems capable of positioning the die substrate and the transfer mechanism along the first direction and along a second direction perpendicular to the first direction without moving the bridge. The movement by the actuator may be limited to along the length of the bridge and a small amount of movement perpendicular to the length of the bridge in an embodiment. In other words, the stage on which the product substrate sits may be movably disposed in the transfer apparatus and may be configured to move either manually and/or via computer-controlled motor(s). Similarly, the one or more bridge structures may be movably mounted on a set of rails of the transfer apparatus and may also be configured to move via computer-controlled motor(s).

Each of the bridges may have a rail or a track disposed thereon that extends substantially perpendicular to the set of rails on which the bridge structure is mounted. The transfer mechanism assembly and the frame carrying the die substrate may be mounted to a same bridge via the aforementioned rail or track, such that the frame carrying the die substrate and/or the transfer mechanism assembly are movable in a second direction that is substantially perpendicular to the first direction in which the bridge structure is movable. In this way, the bridge structure may be moved in a first direction independently of the movement of the frame carrying the die substrate and/or the transfer mechanism assembly in the second direction. In an embodiment, the frame carrying the die substrate may include additional actuators to move the die substrate in the first direction as well as the second direction so as to align die of the die substrate with the transfer mechanism. Additionally, the transfer mechanism may be moveable, relative to the bridge, in the first direction and the second direction by steering the elongated rod or actuating one or more actuation systems coupled to the bridge.

The one or more bridge structures, the frame carrying the die substrate, the transfer mechanism assembly, and/or the product substrate may be moved via computer-controlled motors, so that the transfer mechanism assembly is aligned with the next die to be transferred on the die substrate and the next transfer position on the product substrate. At this point, the pin of the transfer mechanism assembly may be actuated to apply pressure to the die substrate, on the backside of the next die to be transferred, to bring the die in contact with and transfer to the product substrate at the position where the die is to be placed on the product substrate. This process may be repeated until all of the die to be transferred onto the product substrate have been transferred from the die substrate (e.g., wafer tape) to the product substrate.

Note, the conveyance mechanisms (e.g., the bridge structures and associated components) are generally extremely heavy due to the low tolerance of undesired movement, since a minor error in the respective positions thereof may cause improper alignment during a transfer, thereby causing a failure to accurately place a die during a transfer position. That is, the relative bulk weight of the conveyance mechanisms in a transfer system helps to minimize unintentional movements of the components due to structural vibrations from many potential sources including for example terrestrial, human, adjacent machinery, and/or even minor vibrations induced by the motion (e.g., start/stop, transit, etc.) of a systems own conveyance mechanisms. However, the starting and stopping of the heavy componentry of the conveyance mechanisms in conventional systems causes an increase in the overall time to produce accurate consecutive transfers. Accordingly, in an effort to enhance the speed of transfer, as described with respect to embodiments disclosed herein, it may be desirable to reduce the number of conveyance mechanisms in motion during a transfer operation.

In an embodiment, the transfer apparatus may have a first bridge and second bridge (“bridges). Both the first bridge and the second bridge may be movable in a first direction (e.g., along a length or width of the product substrate) along a first rail and a second rail (“rails”), where the first rail and the second rail may be disposed on opposite sides, respectively, of a stage configured to hold the product substrate. Although for the purposes of this description the term “rail” is being used, it should be understood that any suitable guide for movement of the bridges in substantially a single direction (e.g., along the first direction, but not directions with orthogonal components to the first direction) is contemplated according to an embodiment. The bridges may have one or more motor(s) disposed thereon, respectively, to move the bridges along the rails. Alternatively, the bridges may be mechanically coupled to one or more motor(s), such as by way of cable, chain, and/or pulley, to enable movement along the rails.

The first bridge may include two leg portions that engage with the first and second rails, respectively, and a bridge portion that connects between the two leg portions. The bridge portion spans over the stage and/or the product substrate provided on the stage. The bridge portion of the first bridge may have a track or guide disposed along a portion of its length. This track may extend along the bridge portion in a direction substantially perpendicular to the first and second rails to which the first bridge may be movably mounted. The transfer mechanism assembly and die substrate assembly may be disposed movably along this track and may include actuators to provide relatively small (e.g., compared to the movement of the bridge) in a direction perpendicular to the track. The transfer mechanism assembly and die substrate assembly may be mechanically coupled to one or more computer-controlled motors, to move the transfer mechanism assembly and die substrate assembly along the track of the first bridge. In an embodiment, the transfer mechanism assembly may be disposed on the track such that the transfer mechanism assembly and die substrate assembly may be configured to move the full distance across (e.g., width) of the stage and/or the product substrate disposed on the stage.

Similar to the first bridge, the second bridge may also include two leg portions that engage with the first and second rails, respectively, and a bridge portion that connects between the two leg portions. The bridge portion spans over the stage and/or the product substrate provided on the stage. The bridge portion of the second bridge may also have a track or guide disposed along a portion of its length. This track may extend along the bridge portion in a direction substantially perpendicular to the first and second rails to which the second bridge may be movably mounted. A second transfer mechanism assembly and die substrate, as mounted on a frame or holder, may be disposed movably along this track of the second bridge. The die substrate may be mechanically coupled to one or more computer-controlled motors, to move the second transfer mechanism assembly and die substrate, as mounted on the die substrate frame, along the track of the second bridge. In an embodiment, the second transfer mechanism assembly and die substrate frame may be disposed on the track such that the die substrate may be configured to move the full distance across (e.g., width) of the stage and/or the product substrate disposed on the stage and may also be configured to move in a range of less than one to several centimeters perpendicular to the width of the bridge.

The two bridges, as well as the stage, the transfer mechanism assembly, and the die substrate may be moved via a controller to align a die on the first or second die substrate to be transferred with a pin of the first or second transfer mechanism assembly with a location on the product substrate where the die is to be placed. After this alignment, the pin of the transfer mechanism assembly may be actuated to push the die in contact with the product substrate (or the circuit trace on the product substrate, when appropriate) to transfer the die onto the product substrate.

According to an embodiment, a transfer apparatus may include more than one transfer mechanism assembly and more than one die substrate on each of the two bridge structures. This may allow for parallel processing (e.g., small movement of components followed by die transfer) of die being transferred to the product substrate. A transfer apparatus with multiple transfer mechanism assemblies and multiple corresponding die substrates may allow for assembly with different types of die. For example, a micro-sized LED of a particular color may be transferred from a first die substrate, while a micro-sized LED of a different color may be transferred from another die substrate. In another example, a lens or an electrically actuatable element (i.e., capacitor, transistor, controller, etc.) may be transferred from a first substrate, while an LED of any size or color may be transferred from a second substrate.

In an embodiment, a transfer apparatus may include less than or more than two bridge structures (e.g., one, three, four, five, etc.). For example, four bridge structures may be implemented and may be configured to operate in parallel to increase the throughput of product substrates output by the transfer apparatus. As described above, using multiple sets of transfer mechanism assemblies and die substrate holders may also enable diversity by transferring one type of lens or other electrically actuatable element from one set of bridge structures and transferring another type of lens or other electrically actuatable element from another set of bridge structures. In any embodiment, a single bridge structure may implement both a transfer mechanism assembly and a die substrate holder.

In an embodiment, one or more sensors may be implemented to assist the transfer apparatus in determining the precise transfer location and alignment of the components involved in the transfer. Further, a die map may be used to help guide the apparatus to determine which die on a given die substrate should be transferred according to the die quality or other die factors. Sensors and a die map may be implemented similarly as is discussed in U.S. Pat. No. 9,633,883.

Die transfer rates using a transfer apparatus as described herein, in conjunction with multiple transfer mechanisms, as discussed in U.S. application Ser. No. 15/978,094, may permit for a significantly higher transfer rate than is available in the conventional machines. The die transfer rate is the number of die that are transferred per second by the apparatus, which rate may range from about 5-500 die, 50-400 die, 100-300 die, or 150-250 die, for example, placed per second.

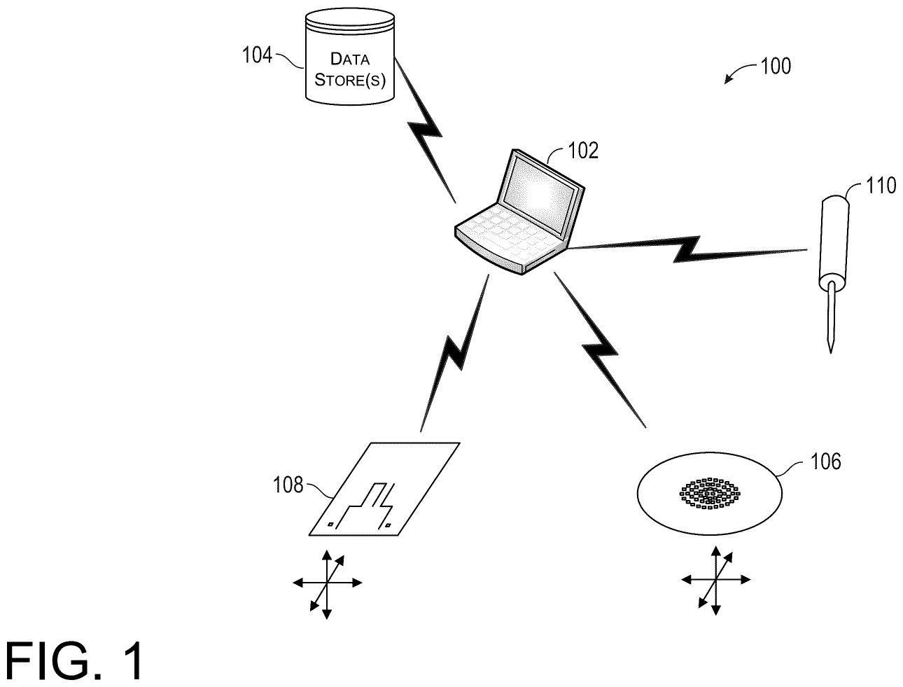

A simplified example of an embodiment of a transfer system 100 is illustrated in FIG. 1. The transfer system 100 may include a personal computer (PC) 102 (or server, data input device, user interface, etc.), a data store 104, a wafer tape mechanism 106, a product substrate mechanism 108, and a transfer mechanism 110. Inasmuch as a more detailed description of the wafer tape mechanism 106, the product substrate mechanism 108, the transfer mechanism 110, has been given heretofore, specific details about these mechanisms is not repeated here. However, a brief description of how the wafer tape mechanism 106, the product substrate mechanism 108, the transfer mechanism 110, relate to interactions between the PC 102 and the data store 104 is described hereafter.

In an embodiment, the PC 102 communicates with data store 104 to receive information and data useful in the transfer process of directly transferring die from a wafer tape in wafer tape mechanism 106 using the transfer mechanism 110 on to a product substrate in the product substrate mechanism 108 whereat the die may be attached to the product substrate. PC 102 may also serve as a receiver, compiler, organizer, and controller of data being relayed to and from each of the wafer tape mechanism 106, the product substrate mechanism 108, and the transfer mechanism 110. PC 102 may further receive directed information from a user of the transfer system 100. Note that, while FIG. 1 depicts directional movement capability arrows adjacent to the wafer tape mechanism 106 and the product substrate mechanism 108, those arrows merely indicate general directions for mobility, however, it is contemplated that both the wafer tape mechanism 106 and the product substrate mechanism 108 may also be configurable to move in other directions including rotation in plane, pitch, roll, and yaw, for example.

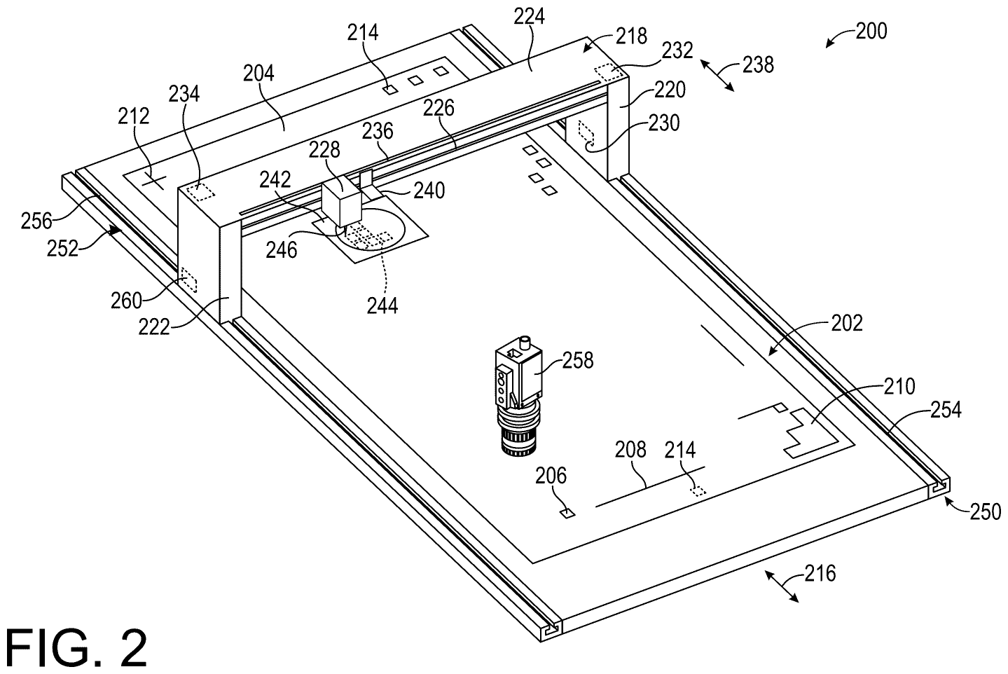

FIG. 2 illustrates a schematic view of a transfer apparatus 200 with bridge structure 218 for transfer of die 244 from a die substrate 242 to a product substrate 204. The transfer apparatus 200 may include a movable stage 202 configured to hold the product substrate 204. The movable stage 202 may be configured to move in one or more directions (e.g., x-direction, y-direction, or both x and y-direction). In an embodiment, the movable stage 202 may also be configured to move up and down (e.g., in the z-direction). For example, the movable stage 202 may be configured, such as by coupling to a motor or other mechanical device, to move in direction 216.

The product substrate 204 may be any suitable material (e.g., PCB, FR-4 board, paper, cardboard, glass, ceramic, plastic, tape, etc.), as described herein. The product substrate 204 may have previously transferred die 206, such as semiconductor die, and/or circuit traces 208 disposed and/or formed thereon and/or therein. The die 206, in an embodiment, may be disposed on the product substrate 204 according to the methods and apparatus as described herein. The circuit traces 208 may be of any suitable type and/or areal density. These circuit traces 208 may be conductive and configured to carry current, such as between a die 206 and one or more other elements of the product substrate 204.

The product substrate 204 may further include alignment features 210, 212 of any suitable type, such as a tree structure or a cross. The alignment features 210, 212 may have known coordinates for a product substrate 204 that may be known to a controller, such as PC 102. The alignment features 210, 212, along with their known coordinates, may be used by the PC 102 to determine positions of various components of the transfer apparatus 200. Thus, the alignment features 210, 212 may be detected, such as by optical imaging, and used for aligning and/or orienting components of the transfer apparatus 200 to transfer the die 244 onto the product substrate 204. The product substrate 204 may further have positions and/or locations 214 where die are to be transferred. In an embodiment, the locations 214 where die are to be transferred may be visually identifiable and may be identified by optical detection. Such visual indicia of the locations 214 where die are to be transferred may also be used to align components of the transfer apparatus 200 to transfer the die 244 onto the product substrate 204. The PC 102 may receive information about the product substrate 204, such as location 214 and/or alignment features 210, 212, in the form of a product substrate data file.

The transfer apparatus 200 may further include a bridge structure 218. The bridge structure 218 may have a first leg 220, a second leg 222, and a bridge portion 224 disposed between the first leg 220 and the second leg 222. The bridge structure 218 may be configured to move along a first rail 250 and a second rail 252. The legs 220, 222 may be movably coupled to the rails 250, 252 allowing the bridge structure 218 to move along the first rail 250 and second rail 252.

The bridge structure 218 may have a rail and/or track 226 disposed along its bridge portion 224. A transfer mechanism assembly 228, as described herein, may be movably mounted on the track 226. The track 226, and therefore, the range of positions of the transfer mechanism assembly 228 may be the same or greater than a width of the product substrate 204 to enable transfer of die 244 onto any suitable location on the product substrate 204. The transfer mechanism assembly 228 may have a pin 246 that can be actuated to extend outward from the transfer mechanism assembly 228 and retracted inward toward the transfer mechanism assembly 228, as described herein.

A die substrate frame 240, holding a die substrate 242 with die 244 thereon, may be movably mounted on the track 226 of the bridge structure 218 independent of the transfer mechanism assembly 228. The track 226, and therefore, the range of positions of the die substrate frame 240 may be the same or greater than a width of the product substrate 204 to enable transfer of die 244 onto any suitable location on the product substrate 204. The die substrate frame 240, as described herein, may be any suitable substrate, such as wafer tape, on which die 244 that are to be transferred to the product substrate 204 are held. In an embodiment, the die substrate frame 240 and the transfer mechanism assembly 228 may be coupled together at the track 226 such that a single motor or conveyance system may move the transfer mechanism assembly 228 and the die substrate frame 240 together. To provide for positioning of the die 244 and the pin 246, actuators of the die substrate frame 240 and/or of the transfer mechanism assembly 228 may be used to position the pin 246 and die 244 relative to one another.

The bridge structure 218 may further include one or more motors 260, 230, 232, 234 to enable the bridge structure 218 to move along the rails 250, 252 and to enable the transfer mechanism assembly 228 to move along track 226. The motor 260 may be encased within the second leg 222, such as within a housing of the second leg 222, and the motor 230 may be encased within the first leg 220. The motors 230, 260 may be computer controlled, such as by PC 102, to exert force on the legs 220, 222 relative to the rails 250, 252 to move the first bridge structure along the rails 250, 252 along the direction 238. The direction 238 may be the same direction as direction 216 along which the movable stage 202 may be configured to move.

Although the motors are depicted as disposed on the legs 220, 222, it should be understood that any suitable coupling of the motors 230, 260 with the legs 220, 222 may be implemented to move the bridge structure 218 along the rails 250, 252. For example, there may be more than one motor per leg 220, 222 of the bridge structure 218. Additionally, in an embodiment, the motors 230, 260 may be located outside of the legs 220, 222 and coupled to each of the legs, respectively, via wire, cable, pulleys, etc.

The motors 232, 234 are coupled with transfer apparatus 200 to move the transfer mechanism assembly 228. For example, motors 232, 234 may be disposed in and/or on the bridge portion 224 of the bridge structure 218. The transfer mechanism assembly 228 may be mechanically coupled to the motors 232, 234 by wire, cable, pulleys, etc. (not shown). The motors 232, 234 may be controlled by PC 102 to move the transfer mechanism assembly 228 along the length of the track 226. The bridge structure 218 may further include one or more sensors 236, such as a linear sensor, for example. The sensor 236 may be configured to provide signals indicative of the position of the transfer mechanism assembly 228 and/or the die substrate 242 along the track 226 of the bridge structure 218. The sensor 236 may be of any suitable type, such as a Hall effect sensor, a magnetic sensor, a capacitive sensor, an optical sensor, a sonic sensor, etc. In an embodiment, sensors, such as an accelerometer (e.g., a micro-electro-mechanical system (MEMS) based accelerometer) or any other suitable sensor may be disposed in or on the transfer mechanism assembly 228 and/or the die substrate frame 240 to indicate the position of the transfer mechanism assembly 228. In other cases, current and voltages input to and/or measured at the input of the motors 232, 234 may be used to determine the position of the transfer mechanism assembly 228 along the track 226 of the bridge structure 218. In an embodiment, a combination of the aforementioned mechanisms, for the purposes of greater precision, accuracy, and/or redundancy, may be used to determine the transfer mechanism assembly 228 position along the track 226 of the bridge structure 218.

It should be understood that a controller, such as the PC 102, may receive signals from sensors 236, a camera 298, and/or any other suitable detectors and position the bridge structure 218 at an intended location. This positioning may correspond to the die 244 that is to be transferred onto the product substrate 204. Additionally, the PC 102 may be configured to position the transfer mechanism assembly 228 along the track 226 of the bridge structure 218. In particular, the PC 102 may control one or more motors to position the bridge structure 218 and the transfer mechanism assembly 228. This positioning, as discussed herein, may also be based at least in part on one or more data files, such as data files indicating the locations on the product substrate 204 where die are to be placed and/or data files that indicate die locations and/or known good die on a die substrate 242.

In an embodiment, the movement of the bridge structure 218 may span substantially the full length of the movable stage 202 and/or the product substrate 204. This allows the bridge structure 218 with the transfer mechanism assembly 228 and the die substrate frame 240 to cooperate with each other to place the die 244 on substantially the full surface of the product substrate 204.

Although the rails 250, 252 are depicted here as a housing with a slot 254, 256 therein, the rails 250, 252 may be of any suitable type. Indeed, any suitable guide, rail, track, or otherwise, may be used for the movement of the bridge structure 218. The transfer apparatus 200 may also include the camera 258, as discussed herein. Signals, such as image signals, may be processed by the PC 102 and used, in conjunction with signals from sensors 236, to control the movement of the bridge structure 218, the transfer mechanism assembly 228, and/or the die substrate frame 240.

The bridge structure 218 may be moved, under the controller of PC 102, along with the transfer mechanism assembly 228 and the die substrate frame 240 to bring a die 244 to be transferred in alignment with the pin 246 and a location 214 on the product substrate where the die 244 is to be placed. The PC 102 may perform this alignment by controlling the one or more motors 230, 260, 232, 234, or other suitable electromechanical devices.

It should be understood that under the control of a controller and based at least in part on information about the product substrate 204 and information about the die substrate frame 240, a die 244 may be aligned with the pin 246 of the transfer mechanism assembly 228 and with the location on the product substrate where the die 244 is to be transferred. When these elements are aligned in two direction (e.g., the x and y directions), the pin 246 may be actuated under the control of the controller (e.g., PC 102) to push the die 244 in a third direction (e.g., the z direction) in contact with the location on the product substrate 204 where the die 244 is to be transferred. The actual occurrence of the transfer may be realized when the adhesive force between the die and the substrate to which the die is to be transferred becomes greater than the adhesive force of retention between the die and the substrate from which the die is being transferred. In an embodiment, the die substrate frame 240 may be actuable in the x and y directions independent of the bridge structure 218 to aid in positioning of the die 244 and the pin 246 at the location 214.

It should be understood that the product substrate 204 and, therefore, the movable stage 202 may be of any suitable size to accommodate the production of current and next generation products. For example, die 244 (e.g., LEDs, micro-sized LEDs, ICs, electrically actuatable elements, etc.) may be attached to relatively small area substrates, such as those used for smart watch PCBs and smart watch displays, or as large as, for example, Gen 10.5 and beyond glass that may be 3.3 meters×2.9 meters in size. Indeed, the transfer apparatus 200 may be scaled in size to be optimized for the products manufactured thereon.

It should be understood that there may be an array of locations where the die 244, the pin 246, and the location 214 on the product substrate 204 could be aligned. Indeed, there are multiple movable elements (e.g., movable stage 202, bridge structure 218, transfer mechanism assembly 228, die substrate frame 240, etc.) that may allow for a choice of an area (in the x and y-directions) where the transfer is to take place. This transfer point may be referred to as the alignment point and may be referenced to an initial reference frame, for which corresponding coordinates on a stage reference frame and/or bridge reference frame may be determined. This alignment point, therefore, may be a point in a fixed reference frame to which the product substrate 204, the pin 246, and the die 244 are to be aligned. Since there may be a choice in where the alignment point is located, various algorithms may be used to determine the alignment point for a particular die transfer process. This alignment point may be determined based at least in part on one or more parameters that may be optimized or thresholded, such as misalignment levels and/or transfer time.

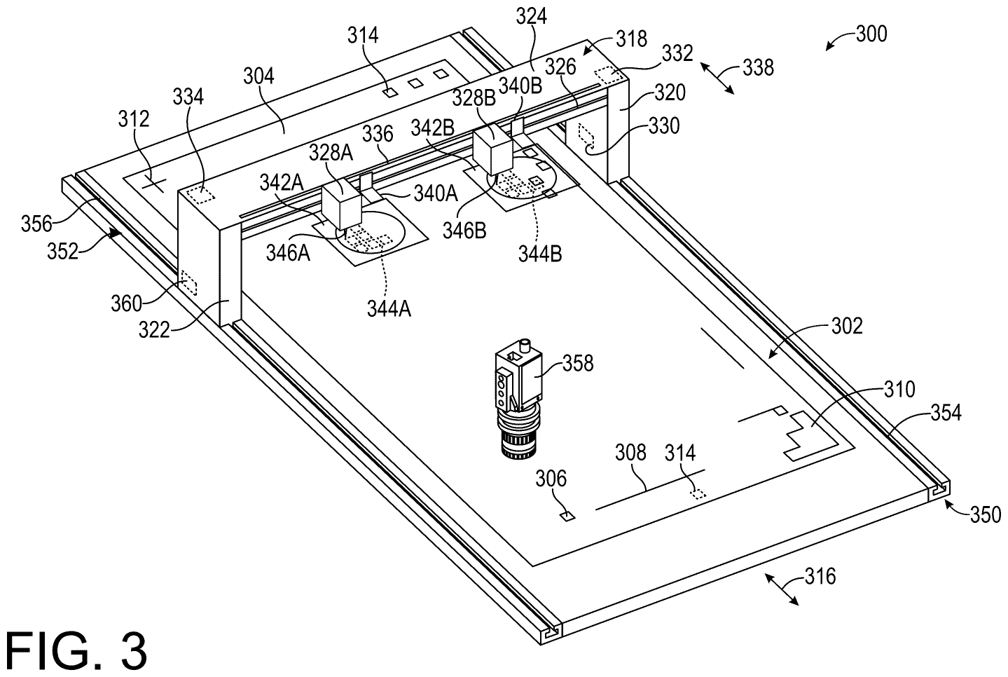

FIG. 3 illustrates a schematic view of an transfer apparatus 300 with multiple transfer mechanism assemblies 328A, 328B and die substrate frames 340A, 340B on a bridge structure 318 for transfer of die from the die substrates 342A, 342B to a product substrate 304 according to an embodiment of this application. The transfer apparatus 300 may include components similar or identical to those described above with respect to FIG. 2. For example, the movable stage 202, product substrate 204, die 206, circuit traces 208, alignment features 210, 212, location 214, direction 216, bridge structure 218, legs 220, 222, bridge portion 224, track 226, motors 230, 260, 232, 234, sensors 236, direction 238, rails 250, 252, slots 254, 256, and camera 258, may correspond to the movable stage 302, product substrate 304, die 306, circuit traces 308, alignment features 310, 312, location 314, direction 316, bridge structure 318, legs 320, 322, bridge portion 324, track 326, motors 330, 360, 332, 334, sensors 336, direction 338, rails 350, 352, slots 354, 356, and camera 358 of FIG. 3.

The bridge structure 318 may have multiple transfer mechanism assemblies 328A, 328B, as described herein with respect the transfer mechanism assembly 228, may be movably mounted on the track 326. The track 326, and therefore, the range of positions of the transfer mechanism assemblies 328 may be the same or greater than a width of the product substrate 304 to enable transfer of die 344A, 344B onto any suitable location on the product substrate 304. The transfer mechanism assemblies 328A, 328B may have pins 346A, 346B that correspond to each assembly that can be actuated to extend outward from the transfer mechanism assemblies 328A, 328B and retracted inward toward the transfer mechanism assemblies 328A, 328B, as described herein.

Multiple die substrate frames 340A, 340B, holding die substrates 342A, 342B with die 344A, 344B thereon, may be movably mounted on the track 326 of the bridge structure 318 independent of the transfer mechanism assemblies 328. The track 326, and therefore, the range of positions of the die substrate frames 340A, 340B may be the same or greater than a width of the product substrate 304 to enable transfer of die 344A, 344B onto any suitable location on the product substrate 304. The die substrate frame 340A, 340B, as described herein, may be any suitable substrate, such as wafer tape, on which die 344A, 344B that are to be transferred to the product substrate 304 are held. In an embodiment, the die substrate frames 340A, 340B and the transfer mechanism assemblies 328A, 328B may be coupled together at the track 326 such that a single motor or conveyance system may move the pairs of transfer mechanism assemblies 328A, 328B and the die substrate frames 340A, 340B together. To provide for positioning of the die 344A, 344B and the pins 346A, 346B, actuators of the die substrate frames 340A, 340B and/or of the transfer mechanism assemblies 328A, 328B may be used to position the pins 346A, 346B and die 344A, 344B relative to one another.

It should be understood that a controller, such as the PC 102, may receive signals from sensors 336, a camera 358, and/or any other suitable detectors and position the bridge structure 318 at an intended location. This positioning may correspond to the die 344 that are to be transferred onto the product substrate 304. Additionally, the PC 102 may be configured to position the transfer mechanism assemblies 328 along the track 326 of the bridge structure 318. In particular, the PC 102 may control one or more motors 330, 360, 346, 348 to position the bridge structure 318 and the transfer mechanism assemblies 328A, 328B as well as the die substrate frames 340A, 340B. This positioning, as discussed herein, may also be based at least in part on one or more data files, such as data files indicating the locations on the product substrate 304 where die are to be placed and/or data files that indicate die locations and/or known good die on a die substrate 342.

In an embodiment, the movement of the bridge structure 318 may span substantially the full length of the movable stage 302 and/or the product substrate 304. This allows the bridge structure 318 with the transfer mechanism assemblies 328 and the die substrate frames 340 to cooperate with each other to place the die 344 on substantially the full surface of the product substrate 304.

It should be understood that the die substrates 342A, 342B may be configured to have the same or different types of die 344 coupled thereto, such that multiple different types of die may be placed simultaneously on the product substrate 304 or the die 344, that may be the same, may be placed more rapidly than a single transfer mechanism assembly would be capable of.

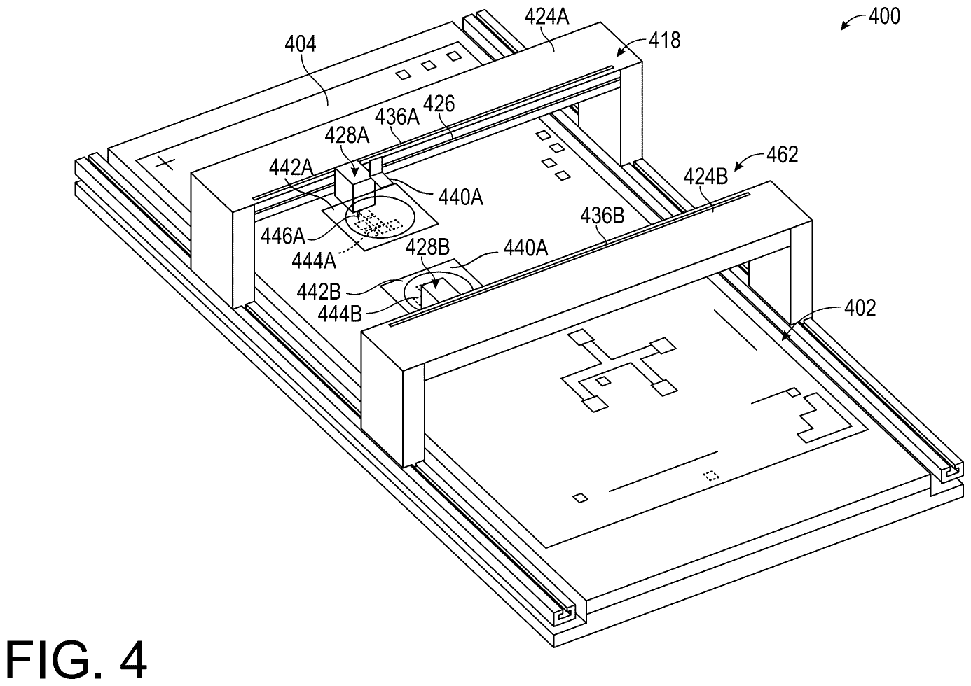

FIG. 4 illustrates a schematic view of an transfer apparatus 400 with a first transfer mechanism assembly 428A and first die substrate frame 440A on a first bridge 418 and a second transfer mechanism assembly 428B and second die substrate frame 440B on a second bridge 462 for transfer of die 444A, 444B from the die substrates 442A, 442B to a product substrate 404 according to an embodiment of this application. The transfer apparatus 400 may include components similar or identical to those described above with respect to FIGS. 2 and 3. For example, the movable stage 202, product substrate 204, bridge structure 218, bridge portion 224, track 226, and sensors 236, may correspond to the movable stage 402, product substrate 404, bridge structures 418 and 462, bridge portion 424, track 426, and sensors 436 of FIG. 4. Additional components described herein may also be included though not specifically shown in FIG. 4.

The bridge structures 418 and 462 may be substantially similar, though are shown as mirrored examples of each other. In an embodiment, the bridge structures 418 and 462 may not be mirrored but may be identical to one another, though independently controllable. Each of the bridge structures 418 and 462 may have a transfer mechanism assembly 428A, 428B, as described herein with respect the transfer mechanism assembly 228, may be movably mounted on the tracks 426A or 426B. The tracks 426A, 426B, and therefore, the range of positions of the transfer mechanism assemblies 428A, 428B may be the same or greater than a width of the product substrate 404 to enable transfer of die 444A, 444B onto any suitable location on the product substrate 404. The transfer mechanism assemblies 428A, 428B may have pins 446A, 446B corresponding to each assembly that can be actuated to extend outward from the transfer mechanism assemblies 428A, 428B and retracted inward toward the transfer mechanism assemblies 428A, 428B, as described herein.

Each of the bridge structures also includes a die substrate frame 440A, 440B, holding die substrates 442A, 442B with die 444A, 444B thereon, and may be movably mounted on the tracks 426A, 426B of the bridge structures 418 and 462 independent of the transfer mechanism assemblies 428A, 428B. The tracks 426A, 426B, and therefore, the range of positions of the die substrate frames 440A, 440B may be the same or greater than a width of the product substrate 404 to enable transfer of die 444A, 444B onto any suitable location on the product substrate 404. The die substrate frames 440A, 440B, as described herein, may be any suitable substrate, such as wafer tape, on which die 444A, 444B that are to be transferred to the product substrate 404 are held. In an embodiment, the die substrate frames 440A, 440B and the transfer mechanism assemblies 428A, 428B may be coupled together at the tracks 426A, 426B such that a single motor or conveyance system may move each of the pairs of transfer mechanism assemblies 428A, 428B and the die substrate frames 440A, 440B together. To provide for positioning of the die 444A, 444B and the pins 446A, 446B, actuators of the die substrate frames 440A, 440B and/or of the transfer mechanism assemblies 428A, 428B may be used to position the pins 446A, 446B and die 444A, 444B relative to one another.

In an embodiment, each of the bridge structures 418 and 462 may include multiple transfer mechanism assemblies 428 and die substrate frames 440, for example as shown and described with respect to FIG. 3 above. In this manner, several different die types may be placed simultaneously on the product substrate 404 and/or the die may be placed with greater speed and efficiency by placing the multiple die simultaneously using the multiple assemblies.

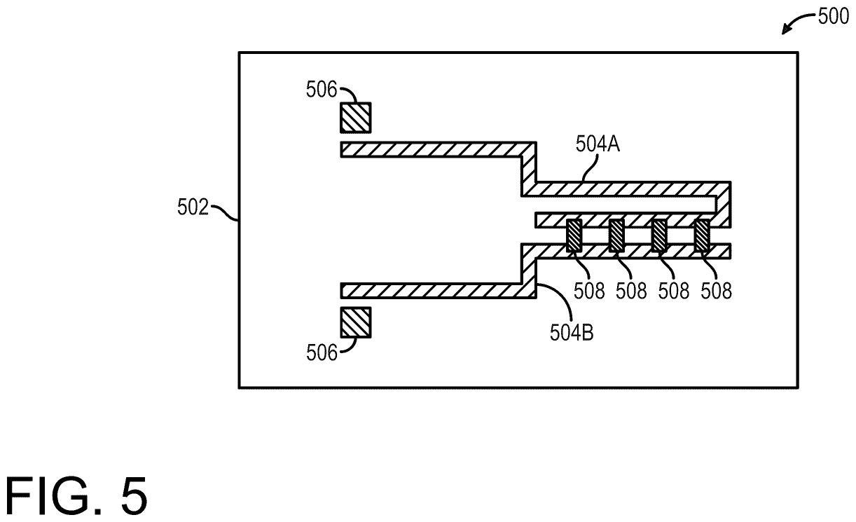

FIG. 5 illustrates an embodiment of a processed product substrate 500. A product substrate 502 may include a first portion of a circuit trace 504A, which may perform as a negative or positive power terminal when power is applied thereto. A second portion of the circuit trace 504B may extend adjacent to the first portion of the circuit trace 504A, and may act as a corresponding positive or negative power terminal when power is applied thereto.

As similarly described above with respect to the wafer tape, in order to determine where to convey the product substrate 502 to perform the transfer operation, the product substrate 502 may have a bar code (not shown) or other identifier, which is read or otherwise detected. The identifier may provide circuit trace data to the apparatus. The product substrate 502 may further include datum points 506. Datum points 506 may be visual indicators for sensing to locate the first and second portions of the circuit trace 504A, 504B. Once the datum points 506 are sensed, a shape and relative position of the first and second portions of the circuit trace 504A, 504B with respect to the datum points 506 may be determined based on preprogrammed information.

Additionally, die 508 are depicted in FIG. 5 as straddling between the first and second portions of the circuit trace 504A, 504B. In this manner, the electrical contact terminals (not shown) of the die 508 may be bonded to the product substrate 502 during a transfer operation, such as by transfer apparatus 200, 300, and/or 400. Accordingly, power may be applied to run between the first and second portions of the circuit trace 504A, 504B, and thereby powering die 508. For example, the die may be unpackaged LEDs that were directly transferred from a wafer tape to the circuit trace on the product substrate 502. Thereafter, the product substrate 502 may be processed for completion of the product substrate 502 and used in a circuit or other final product. Further, other components of a circuit may be added by the same or other mechanism of transfer to create a complete circuit, and may include control logic to control LEDs as one or more groups in some static or programmable or adaptable fashion.

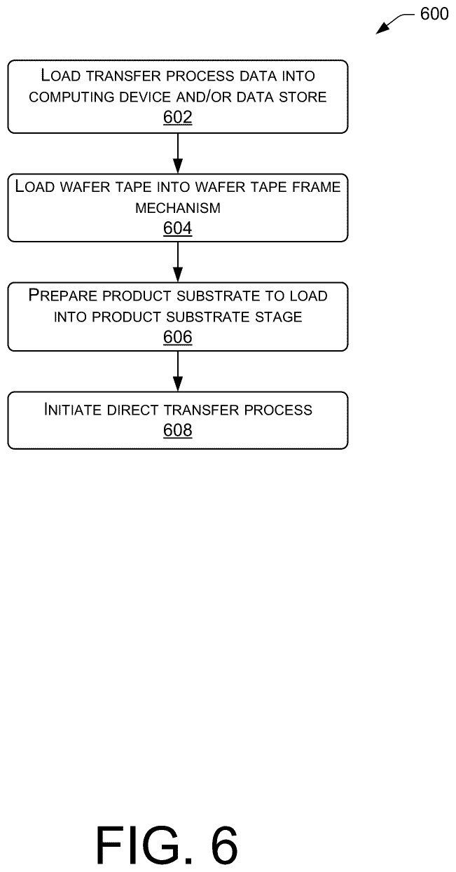

A method 600 of executing a direct transfer process, in which one or more die is directly transferred from a die substrate, such as wafer tape, to a product substrate, is illustrated in FIG. 6. The processes of the method 600 described herein may not be in any particular order and as such may be executed in any satisfactory order to achieve a desired product state. The method 600 may include a step 602 of loading transfer process data into a PC 102 and/or a data store. The transfer process data may include data such as die map data, circuit CAD files data, and/or needle profile data.

An operation of loading a wafer tape onto a wafer tape frame mechanism 604 may also be included in method 600. Loading the wafer tape into the wafer tape frame, such as die substrate frames 240, 340, 440, may include controlling the die frame to move to a load position. In other embodiments, loading the wafer tape into the wafer tape frame may not require moving the wafer tape frame to a load position. The wafer tape, such as die substrate 242, may be secured in the wafer tape frame mechanism in the load position. The wafer tape may be loaded so that the die of the semiconductor, such as die 244, are facing downward toward the product substrate conveyor mechanism.

The method 600 may further include a step 606 of preparing the product substrate to load into the product substrate stage. Preparing the product substrate may include a step of screen printing a circuit trace on the product substrate according to the pattern of the CAD files being loaded into the PC or data store. Additionally, datum points may be printed onto the circuit substrate in order to assist in the transfer process. The product substrate stage, such as movable stage 202, may be controlled to move to a load position, whereat the product substrate, such as product substrate 204, may be loaded into the product substrate stage. The product substrate may be loaded so that the circuit trace faces toward the die on the wafer. In an embodiment, for example, the product substrate may be delivered and placed in the load position by a conveyor (not shown) or other automated mechanism, such as in the style of an assembly line. Alternatively, the product substrate may be manually loaded by an operator.

Once the product substrate is properly loaded onto the movable stage and the wafer tape is properly loaded into the wafer tape frame, a program to control the direct transfer of the die from the wafer tape to the circuit trace of the product substrate may be executed via the PC 102 to initiate the direct transfer operation 608. The details of the direct transfer operation are described herein.

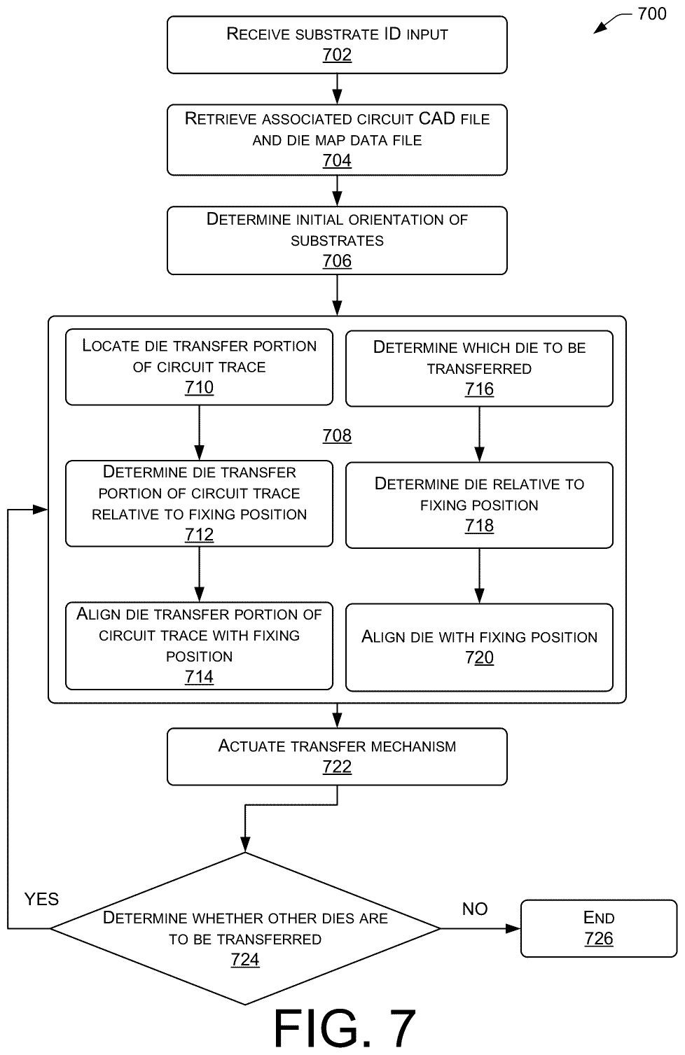

A method 700 of the direct transfer operation of causing die to be transferred directly from the wafer tape (or other substrate holding die, also called a “die substrate” for simplified description of FIG. 7) to the product substrate is illustrated in FIG. 7. The operations of the method 700 described herein may not be in any particular order and as such may be executed in any satisfactory order to achieve a desired product state.

In order to determine which die to place on the product substrate and where to place the die on the product substrate, the PC 102 may receive input regarding the identification of the product substrate and the identification of the die substrate containing the die to be transferred 702. This input may be entered manually by a user, or the PC 102 may send a request to the cell managers in control, respectively, of the product substrate alignment sensor and the die detector. The request may instruct the sensor to scan the loaded substrate for an identification marker, such as a barcode or QR code; and/or the request may instruct the detector to scan the loaded die substrate for an identification marker, such as a barcode or QR code.

Using the product substrate identification input, the PC 102 may query the data store or other memory to match the respective identification markers of the product substrate and the die substrate and retrieve the associated data files 704. In particular, the PC 102 may retrieve a circuit CAD file associated with the product substrate that describes the pattern of the circuit trace on the product substrate. The circuit CAD file may further contain data such as the number of, relative positions of, and respective quality requirement of, the die to be transferred to the circuit trace. Likewise, the PC may retrieve a die map data file associated with the die substrate that provides a map of the relative locations of the specific die on the die substrate.

In the process of executing a transfer of a die to the product substrate, the PC 102 may determine the initial orientation of the product substrate and the die substrate relative to the transfer mechanism and the fixing mechanism. Within process 706, the PC 102 may instruct the substrate alignment sensor to locate datum points on the product substrate. As discussed above, the datum points may be used as reference markers for determining the relative location and orientation of the circuit trace on the product substrate. Further, the PC 102 may instruct the die detector to locate one or more reference points on the die substrate to determine the outlay of the die.

Once the initial orientation of the product substrate and die substrate are determined, the PC 102 may instruct the respective product substrate and die substrate conveyance mechanisms to orient the product substrate and die substrate, respectively, into a position of alignment with the transfer mechanism and the fixing mechanism.

The alignment step 708 may include determining the location of the portion of the circuit trace to which a die is to be transferred at step 710, and where the portion is located relative to the transfer fixing position. The transfer fixing position may be considered to be the point of alignment between the transfer mechanism and the product substrate. Based on the data determined in steps 710 and 712, the PC 102 may instruct the product substrate conveyance mechanism to convey the product substrate so as to align the portion of the circuit trace to which a die is to be transferred with the transfer fixing position 714.

The alignment step 708 may further include determining which die on the die substrate will be transferred at step 716, and where the die is located relative to the transfer fixing position. Based on the data determined in steps 716 and 718, the PC 102 may instruct the wafer tape conveyance mechanism to convey the die substrate so as to align the die to be transferred with the transfer fixing position 720. Conveying the die substrate may include instructing both a bridge structure and a die substrate frame to be positioned at the transfer location. In examples described herein, the bridge may be aligned with the transfer location along a first direction while the frame is positioned by moving along a second direction. Conveyance may also include conveying a transfer mechanism assembly to the location, for example by actuating the transfer mechanism assembly and the die substrate frame along the bridge structure to the location.

Once the die to be transferred from the die substrate and the portion of the circuit trace to which a die is to be transferred are aligned with the transfer mechanism, the needle may be actuated 722 to effectuate the transfer of the die from the die substrate to the product substrate.

After a die is transferred, the PC 102 may determine whether additional die are to be transferred 724. In the case where another die is to be transferred, the PC may revert to alignment step 708 and realign the product and die substrates accordingly for a subsequent transfer operation. In the case where there will not be another die transferred, the transfer process is ended 726.

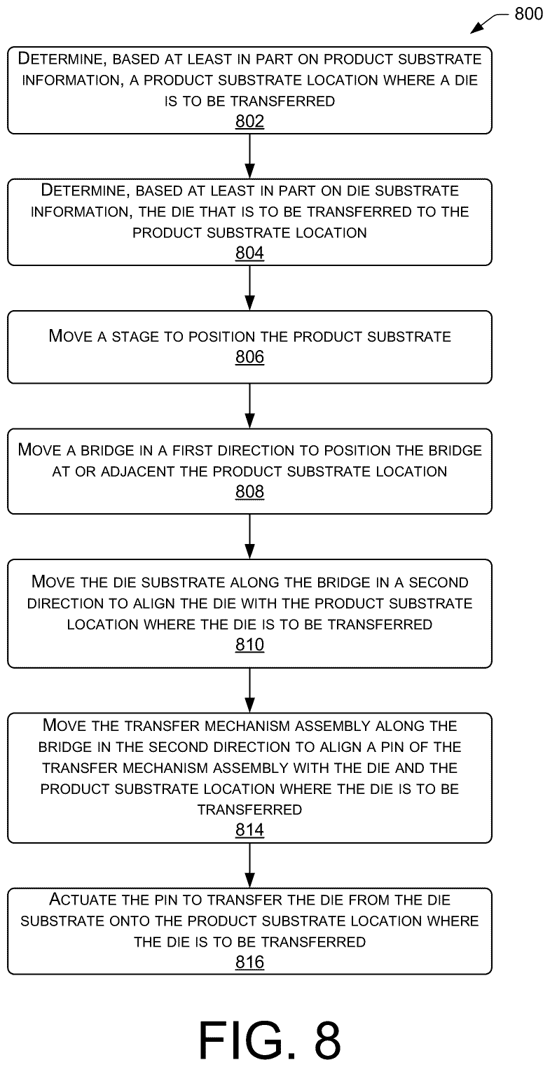

FIG. 8 illustrates a method 800 of a die transfer process from a die substrate held by a first bridge and a transfer mechanism assembly held by a second bridge, according to an embodiment of this application. Method 800 may be performed by any suitable controller of the transfer apparatus 200, 300, 400, such as PC 102.

At block 802, a product substrate location where a die is to be transferred may be determined based at least in part on product substrate information. In an embodiment, the locations for die attachment may be indicated in a data file corresponding to the product substrate information. For example, coordinates on the product substrate may be indicated where the die are to be transferred on to the product substrate. Additionally, or alternatively, image data, such as from a video camera or other image sensor may indicate visible and/or optical indicia (e.g., an orange line) where a die is to be transferred.

At block 804, the die that is to be transferred to the product substrate location may be determined based at least in part on die substrate information. The die substrate information may be in a die substrate information data file that provides a map and/or otherwise indicates coordinates on the die substrate where the die are located. Additionally, in an embodiment, the die substrate information may include an indication of known good die, or at least suspected good die, on the die substrate. This way, known bad die or suspected bad die can be avoided from being transferred on to the product substrate. In an embodiment, the next die to be transferred may be selected as the next good die on the die substrate as proceeding in a rastered progression.

At block 806, the product substrate may be positioned by moving a movable stage. The location on the product substrate where the die is to be attached may be moved to a particular alignment position where the die to be attached and the pin of the transfer mechanism assembly may be moved. In an embodiment, the product substrate may only be moved in a single direction (e.g., x-direction), and in other cases, the product substrate may be moved in two directions (e.g., x-direction and y-direction). In an embodiment, the product substrate on the movable stage may not be moved at all. As discussed herein, movement of the stage may be by way of one or more motors or other electromechanical components controlled by a controller of the transfer apparatus. In an embodiment, the positioning of the stage, and thereby the determination of an alignment location where the die transfer is performed, may be based at least in part on optimizing one or more parameters and/or by requiring one or more parameters to meet certain criteria. For example, the alignment point may be selected in a manner that optimizes expected transfer accuracy and/or expected transfer time.

At block 808, a bridge may be moved to position the bridge at or adjacent the product substrate location. The bridge may be moved in a first direction relative to the product substrate. This movement may be performed by controlling one or more motors or other electromechanical devices configured to move the first bridge along a pair of rails.

At block 810, the die substrate may be moved along the bridge in a second direction to align the die with the product substrate location where the die is to be transferred. This movement may be performed by controlling one or more motors or other electromechanical devices configured to move the die substrate frame or holder along track of the bridge.

At block 812, the transfer mechanism assembly may be moved along the bridge to align a pin of the transfer mechanism assembly with the die and the product substrate location where the die is to be attached. This movement may be performed by controlling one or more motors or other electromechanical devices configured to move the transfer mechanism assembly along a track of the bridge.

At block 816, the pin may be actuated to transfer the die from the die substrate onto the product substrate location where the die is to be attached. This pin may push the die into a position to transfer onto the product substrate.

Although several embodiments have been described in language specific to structural features and/or methodological acts, it is to be understood that the claims are not necessarily limited to the specific features or acts described. Rather, the specific features and acts are disclosed as illustrative forms of implementing the claimed subject matter. Furthermore, the use of the term “may” herein is used to indicate the possibility of certain features being used in one or more various embodiments, but not necessarily in all embodiments.

What is claimed is:

1. An apparatus for transferring a semiconductor die (“die”) from a first substrate to a second substrate, the apparatus comprising:
a first rail extending along a first direction;
a second rail extending along the first direction;
a bridge structure movably mounted to the first rail and the second rail so as to be movable along the first direction, the bridge structure including a track extending along a second direction that is substantially perpendicular to the first direction;
a transfer mechanism assembly including a needle, the transfer mechanism assembly being movably mounted to the track of the bridge structure to move along the second direction;
a die substrate holder configured to secure the first substrate, the die substrate holder being movably mounted to the track of the bridge structure to move along the second direction; and
a controller configured to:
control movements of the bridge structure, the transfer mechanism assembly, and the die substrate holder to align the die on the first substrate with the needle of the transfer mechanism assembly with a transfer position on the second substrate where the die is to be transferred, and
actuate the needle to push the die into the transfer position on the second substrate.

2. The apparatus of claim 1, further comprising a movable stage to support the second substrate, the movable stage configured to move the second substrate along at least one of the first direction or the second direction,
wherein the movable stage is disposed between the first rail and the second rail, and
wherein the controller is configured to control movement of the movable stage.

3. The apparatus of claim 2, wherein the controller is further configured to determine a point of alignment coinciding with the transfer position on the second substrate, the point of alignment to be determined based at least in part on one or more of: (i) a predicted time to transfer the die on the second substrate; or (ii) a predicted placement accuracy of the die on the second substrate.

4. The apparatus of claim 1, further comprising an optical sensor positioned to sense a location of the die on the first substrate with respect to the transfer position on the second substrate.

5. The apparatus of claim 1, further comprising:
a first motor to move the bridge structure along the first rail and the second rail;
a second motor to move the transfer mechanism assembly along the track of the bridge structure; and
a third motor to move the die substrate holder along the track of the bridge structure,
wherein the controller is communicatively coupled to the first motor to move the bridge structure in the first direction, the second motor to move the transfer mechanism assembly in the second direction, and the third motor to move the die substrate in the second direction, to align the die on the first substrate with the needle of the transfer mechanism assembly with the transfer position on the second substrate.

6. The apparatus of claim 1, further comprising a first sensor to provide the controller an indication of where the transfer mechanism assembly is located along the track of the bridge structure.

7. The apparatus of claim 1, wherein the transfer position is a first transfer position, and,
wherein the apparatus further comprises:
a second transfer mechanism assembly including a needle and being movably mounted on the track of the bridge structure; and
a second die substrate holder configured to secure a third substrate having at least a second die thereon, the second die substrate holder being movably mounted on the track of the bridge structure, and
wherein the controller is further configured to:
control movements of the second transfer mechanism assembly in the second direction and the second die substrate holder in the second direction to align a second die on the third substrate and the needle of the second transfer mechanism assembly with a second transfer position on the second substrate where the second die is to be transferred, and actuate the needle of the second transfer mechanism to push the second die into the second transfer position on the second substrate.

8. The apparatus of claim 1, further comprising a first sensor to provide the controller an indication of where the die substrate holder is located along the track of the bridge structure.

9. A method for transferring a die from a first substrate to a second substrate comprising:
moving a bridge along a set of parallel rails;
moving a transfer mechanism assembly along a first track of the bridge;
moving a die substrate holder along a second track of the bridge, the die substrate holder holding the first substrate having the die thereon, aligning a pin of the transfer mechanism assembly with the die on the first substrate in a transfer position on the second substrate; and
actuating the pin to push the die into the transfer position on the second substrate.

10. The method of claim 9, wherein the die is a first die, and
wherein the method further comprises:
moving a second transfer mechanism assembly along the first track of the bridge;
moving a second die substrate holder, securing a third substrate having at least a second die thereon, along the second track of the bridge,
aligning a pin of the second transfer mechanism assembly with the second die on the third substrate and a second transfer position on the second substrate; and
actuating the pin of the second transfer mechanism to push the second die into the second transfer position on the second substrate.

11. The method of claim 9, wherein aligning the pin of the transfer mechanism assembly with the die on the first substrate in the transfer position on the second substrate comprises actuating the die transfer substrate along at least one of the first direction or the second direction independent of movement of the bridge.

12. The method of claim 9, further comprising moving a movable stage on which the second substrate is disposed such that the position on the second substrate is moved to an alignment point based at least in part on optimizing one or more alignment parameters.

13. The method of claim 9, further comprising determining, based at least in part on an optical sensor signal, a location of the die on the first substrate with respect to the transfer position on the second substrate,
wherein aligning the pin of the transfer mechanism assembly with the die on the first substrate is based at least in part on the location.

14. The method of claim 9, further comprising receiving a sensor signal indicative of a position of the transfer assembly along the first track of the bridge,
wherein moving the transfer mechanism assembly along the first track of the bridge is based at least in part on the sensor signal.

15. An apparatus for transferring a semiconductor die (“die”) from a first substrate to a second substrate, the apparatus comprising:
a stage configured to hold a product substrate;
a bridge coupled to a transfer mechanism assembly and a die substrate holder configured to hold the first substrate; and
a controller configured to cause the bridge, the transfer mechanism assembly, and the die substrate holder to move to align the transfer mechanism assembly with the die on the first substrate with a transfer position on the second substrate where the die is to be transferred.

16. The apparatus of claim 15, wherein the transfer mechanism assembly includes:
a needle, and
a needle actuator that moves the needle toward and away from the transfer position on the product substrate responsive to a signal from the controller, and
wherein the needle actuator is configured to push the needle against the die to push the die into the transfer position on the second substrate.

17. The apparatus of claim 15, further comprising a sensor in communication with the controller, the sensor configured to indicate a position of the transfer mechanism assembly on the bridge.

18. The apparatus of claim 15, wherein the bridge is configured to move along a pair of parallel rails in a first direction, the transfer mechanism assembly configured to move along a track disposed on the bridge, and the die substrate holder configured to move along the track.

19. The apparatus of claim 18, wherein the die substrate holder is configured to position the first substrate along a first direction and a second direction, the first direction perpendicular to the second direction.

20. The apparatus of claim 15, further comprising an optical sensor positioned to sense a position of the die with respect to the transfer position on the second substrate.
